(19) United States
(12) Patent Application Publication
(10) Pub. No.: US 2020/0028009 A1
(43) Pub. Date: Jan. 23, 2020

(54) SOLAR BATTERY

(71) Applicant: TOHOKU UNIVERSITY, Miyagi (JP)

(72) Inventors: Shigetoshi SUGAWA, Miyagi (JP); Rihito KURODA, Miyagi (JP)

(73) Assignee: TOHOKU UNIVERSITY, Miyagi (JP)

(21) Appl. No.: 16/476,189

(22) PCT Filed: Jan. 10, 2017
(86) PCT No.: PCT/JP2017/000401

§ 371 Date: Jul. 5, 2019

(51) Int. Cl. H01L 31/0352; H01L 31/18; H01L 31/068

(52) U.S. Cl. CPC H01L 31/035272; H01L 31/068; H01L 31/1804

(57) ABSTRACT

To provide a solar battery that is not affected or substantially not easily affected by an irradiation history of UV light, and thus does not or substantially does not suffer degradation of service life. The above-described problem is solved by a solar battery (100, 200, 200B) provided with a UV degradation preventing layer (109, 205, 205B) under specific conditions as a layer component. The UV deterioration preventing layer (109, 205, 205B) has a layer thickness (d1+d2) within a range of 2 to 60 nm, and contains semiconductor impurities contributing to a semiconductor polarity distributed in concentration in a layer thickness direction and having a maximum value (C_{D}Max) of the concentration distribution in an interior thereof. The maximum value (C_{D}Max) is within a range of 1×10¹⁹/cm³≤Maximum value (C_{D}Max)≤4×10²⁰/cm³ . . . Formula (1), and has a half value (b1) at a depth position (A1) from a surface on a light incident side of the UV deterioration preventing layer. The depth position (A1) is within a range of Depth position (A0) of Maximum value (C_{D}Max)<(“Depth position (A1)”)≤20 nm . . . Formula (3).

### FIELD OF THE INVENTION

The present invention relates to a solar battery.

### DESCRIPTION OF THE BACKGROUND ART

A so-called solar battery, which generates photovoltaic power by receiving natural light or artificial light and supplies electric power externally is a power device that converts light energy to electric power by using a photovoltaic effect, and continues to increase expectations as a renewable energy power device superior in environmental load reduction.

Current common solar batteries include silicon-based and compound-based solar batteries having a structure in which P-type and N-type semiconductors are joined (PN junction type solar battery) (Patent Documents 1 and 2).

In the present application, the term “solar battery” used below refers to any one or more of a single cell (single solar cell), a plurality of cells, and panel-like products (solar panels or solar modules, so-called solar arrays) for which the required voltage and current can be obtained by connecting a plurality of cells in series or in parallel, unless otherwise stated.

On the other hand, in an attempt to achieve efficient absorption of incident light in the solar battery interior, there have been proposed methods that utilize as a texture structure a porous silicon structure formed by a mechanical processing method, a reactive ion etching method, a texture (fine unevenness) structure formation method not dependent on crystal plane orientation, an electrochemical reaction method, a chemical etching method, or the like, for example (Patent Documents 1 to 9).

Any of the above-described proposals is an attempt to efficiently absorb the irradiation light in the solar battery interior through multiple reflection of the irradiation light by the fine uneven structure.

### PATENT DOCUMENTS

Patent Document 1: Japanese Laid-Open Patent Application No. H08-204220
Patent Document 2: Japanese Laid-Open Patent Application No. H10-078194

### Patent Document 3: Japanese Laid-Open Patent Application No. 2002-299661

### Patent Document 4: Japanese Laid-Open Patent Application No. 2008-05327

### Patent Document 5: Japanese Laid-Open Patent Application No. 2012-104733

### Patent Document 6: Japanese Laid-Open Patent Application No. 2014-033046

### Patent Document 7: Japanese Laid-Open Patent Application No. 2014-229576

Patent Document 8: Japanese Laid-Open Patent Application No. H05-2218469

### Patent Document 9: WO 2013/186945

### SUMMARY OF THE INVENTION

### Problems to be Solved by the Invention

Nevertheless, no matter to what extent the power generation efficiency (hereinafter also referred to as photovoltaic power generation efficiency or photoelectric conversion efficiency in a broader sense) is improved by increasing the utilization efficiency of the irradiation light through such structural ingenuity as described above, problems exist in terms of the following.

That is, in addition to visible light, ultraviolet light (UV light) is also included in sunlight, but this UV light, particularly UV light of a light wavelength of about 350 nm or less, has high energy (exceeding about 3.5 eV). Therefore, when UV light is irradiated onto the solar battery, a fixed charge and an interface state can be produced in the oxide film (natural oxide film) formed on the surface of the silicon layer of the solar battery interior, or on the interface between the oxide film and the silicon layer. The fixed charge and the interface state remain (accumulate) in the oxide film and on the interface, and thus their residual amounts increase along with the irradiation history of UV light.

When the fixed charge and the interface state continue to increase in this way, an internal electric field that moves electrons or positive holes (electrons when the silicon layer is the P-type, positive holes when the N-type) generated by light irradiation in the vicinity below the surface of the silicon layer to the silicon layer surface is produced. When this happens, the electrons or positive holes generated by light irradiation move to the silicon layer surface by the formed internal electric field, recombine with the electrons or positive holes accumulated on the silicon layer surface (photo-generated electrons recombine with the accumulated holes and photo-generated holes recombine with the accumulated electrons), and disappear. Therefore, the electrons or positive holes generated by light irradiation do not contribute to the generated current.

For this reason, the power generation efficiency of the solar battery lowers along with the irradiation history of UV light, and eventually the solar battery no longer has enough durability for practical use. This shortens the service life of the solar battery. Ironically, this deterioration of the solar battery due to UV light irradiation is more remarkable in an installation location having a large amount of irradiation light, such as the equator. In such an environment, the service life is short, decreasing the return on investment.

For the purpose of suppressing such deterioration caused by UV light, there is a technique of coating and sealing a solar battery cell with a sealing material containing a weather-proof agent such as an ultraviolet absorber, a light stabilizer, and the like.

However, this technique deviates from the view of increasing power generation efficiency by effectively utilizing UV light, and causes an increase in the number of manufacturing processes and the cost of the solar battery cell.

The UV light addressed in the present application is described below.

While the wavelength region may differ somewhat according to the method of classification, the ultraviolet rays (UV light) of each classified wavelength region are given the names below.
Near ultraviolet rays (wavelength: 380 to 200 nm)
UV-A (wavelength: 380 to 315 nm)
UV-B (wavelength: 315 to 280 nm)
UV-C (wavelength: 280 to 200 nm)
Far ultraviolet rays (far UV, FUV) or vacuum ultraviolet rays (vacuum UV, VUV; collectively referred to as far ultraviolet rays below; wavelength: 200 to 10 nm)
Extreme ultraviolet rays (extreme UV, EUV, or XUV; wavelength: 10 to 1 nm). However, in photolithography and laser technology, far ultraviolet rays (deep UV, DUV) differ from the FUV described above, and refer to ultraviolet rays having a wavelength of 300 nm or less.

The present invention has been made in earnest in view of the above-described points, and an object of the present invention is to provide a solar battery that is not affected or substantially not easily affected by an irradiation history of UV light, and thus does not or substantially does not suffer degradation of service life.

Another object of the present invention is to provide a solar battery capable of maintaining an expected power generation efficiency without causing usage deterioration.

Yet another object of the present invention is to provide a solar battery that is excellent in UV light resistance and can be expected to improve power generation efficiency by effectively using UV light.

### Means for Solving the Problems

An aspect of the present invention lies in a solar battery comprising:

an n-type or p-type silicon (Si) semiconductor substrate;

a semiconductor layer having a polarity (II) opposite to a polarity (I) of the semiconductor substrate and forming a semiconductor junction with the semiconductor substrate; and

a UV deterioration preventing layer provided directly on the semiconductor layer, having a polarity (III) opposite to the polarity (II), having a layer thickness (d1+d2) within a range of 2 to 60 nm, and containing semiconductor impurities of the polarity (III) including semiconductor impurities contributing to the polarity (III) distributed in concentration in a layer thickness direction and having a maximum value (C_{D}Max) of the concentration distribution in an interior thereof, wherein

the maximum value (C_{D}Max) is within the following range:

1×10¹⁹/cm³≤Maximum value (C_{D}Max)≤4×10²⁰/cm³ Formula (1)

and has a half value (b1) at a depth position (A1) from a surface of the UV deterioration preventing layer on a light incident side, and

the depth position (A1) is within the following range:

Depth position (A0) of Maximum value (C_{D}Max)<(“Depth position (A1)”)≤20 nm Formula (3)

Another aspect of the present invention lies in a solar battery comprising:

a photovoltaic power generating layer including a semiconductor junction; and

a UV degradation preventing layer provided directly on the photovoltaic power generating layer, wherein

the UV deterioration preventing layer has a layer thickness (d1+d2) within a range of 2 to 60 nm, and contains semiconductor impurities including semiconductor impurities contributing to the semiconductor polarity of the UV deterioration preventing layer distributed in concentration in a layer thickness direction and having a maximum value (C_{D}Max) of the concentration distribution in an interior thereof,

the maximum value (C_{D}Max) is within the following range:

1×10¹⁹/cm³≤Maximum value (C_{D}Max)≤4×10²⁰/cm³ Formula (1)

and has a half value (b1) at a depth position (A1) from a surface of the UV deterioration preventing layer on a light incident side, and.

the depth position (A1) is within the following range:

Depth position (A0) of Maximum value (C_{D}Max)<(“Depth position (A1)”)≤20 nm Formula (3)

### Effect of the Invention

According to the present invention, it is possible to provide a solar battery that is not affected or substantially not easily affected by an irradiation history of UV light, and thus does not or substantially does not suffer degradation of service life. It is also possible to provide a solar battery capable of maintaining an expected power generation efficiency without causing usage deterioration.

Further, it is also possible to provide a solar battery that is excellent in UV light resistance and can be expected to improve power generation efficiency by effectively using UV light.

Other features and advantages of the present invention will be apparent from the following descriptions taken in conjunction with the accompanying drawings. It should be noted that, in the accompanying drawings, the same reference numerals denote the same or similar components.

### BRIEF DESCRIPTION OF THE DRAWINGS

The accompanying drawings, which are incorporated in and constitute a part of the specification, illustrate embodiments of the present invention and, together with the description, serve to explain the principles of the present invention.

FIG. 1A is a schematic configuration explanatory diagram for explaining a configuration of one example of a preferred embodiment of a solar battery of the present invention.

FIG. 1B is a graph showing one of preferred examples of an effective semiconductor impurity distribution concentration (C_{D}) contained in a photovoltaic power generating part of the solar battery illustrated in FIG. 1A.

FIG. 1C is a graph showing one of the preferred examples of the effective semiconductor impurity distribution concentration (C_{D}) contained in the photovoltaic power generating part of the solar battery illustrated in FIG. 1A.

FIG. 1D is a graph showing one of the preferred examples of the effective semiconductor impurity distribution concentration (C_{D}) contained in the photovoltaic power generating part of the solar battery illustrated in FIG. 1A.

FIG. 1E is a graph showing one of the preferred examples of the effective semiconductor impurity distribution concentration (C_{D}) contained in the photovoltaic power generating part of the solar battery illustrated in FIG. 1A.

FIG. 1F is a graph showing one of the preferred examples of the effective semiconductor impurity distribution concentration (C_{D}) contained in the photovoltaic power generating part of the solar battery illustrated in FIG. 1A.

FIG. 1G is a graph showing one of the preferred examples of the effective semiconductor impurity distribution concentration (C_{D}) contained in the photovoltaic power generating part of the solar battery illustrated in FIG. 1A.

FIG. 1H is a graph showing one of the preferred examples of the effective semiconductor impurity distribution concentration (C_{D}) contained in the photovoltaic power generating part of the solar battery illustrated in FIG. 1A.

FIG. 1I is a graph showing one of the preferred examples of the effective semiconductor impurity distribution concentration (C_{D}) contained in the photovoltaic power generating part of the solar battery illustrated in FIG. 1A.

FIG. 2 is a schematic configuration explanatory diagram for explaining a configuration of another example of the preferred embodiment of the solar battery of the present invention.

FIG. 2A is a schematic top view of the solar battery illustrated in FIG. 2.

FIG. 2B is a schematic configuration explanatory diagram for explaining a configuration of yet another example of the preferred embodiment of the solar battery of the present invention.

FIG. 3 is a graph showing an example of a spectral sensitivity characteristic of an example of the present invention.

FIG. 4 is a graph showing an example of the spectral sensitivity characteristic of a comparative example.

### DESCRIPTION OF THE PREFERRED EMBODIMENTS

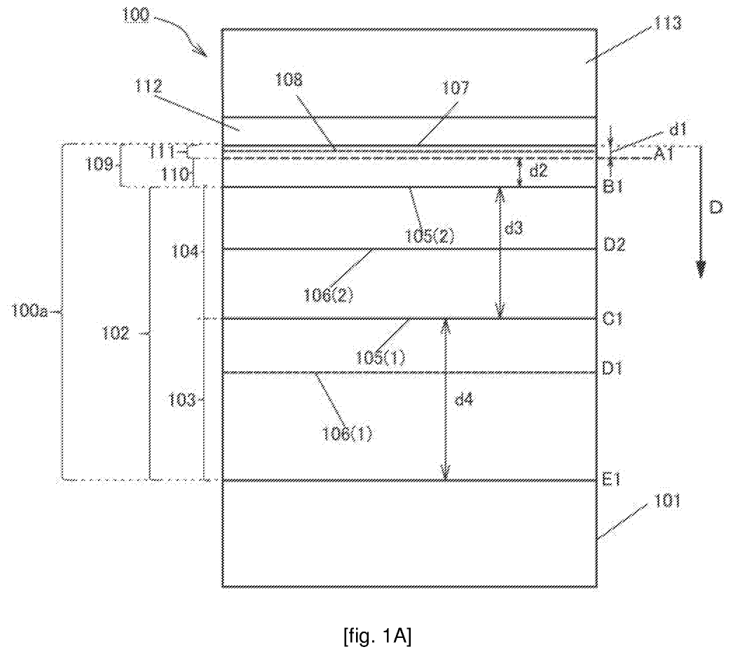

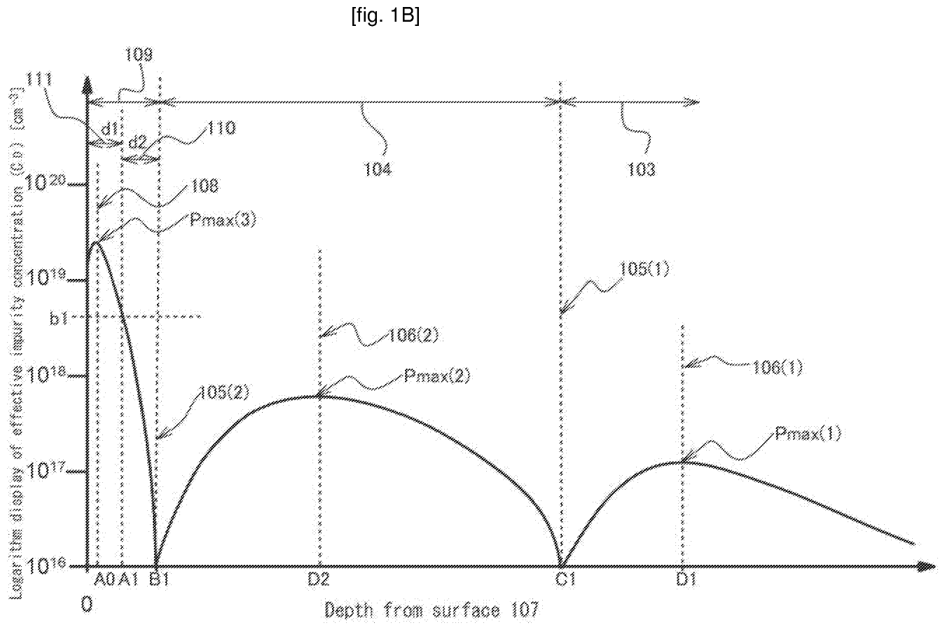

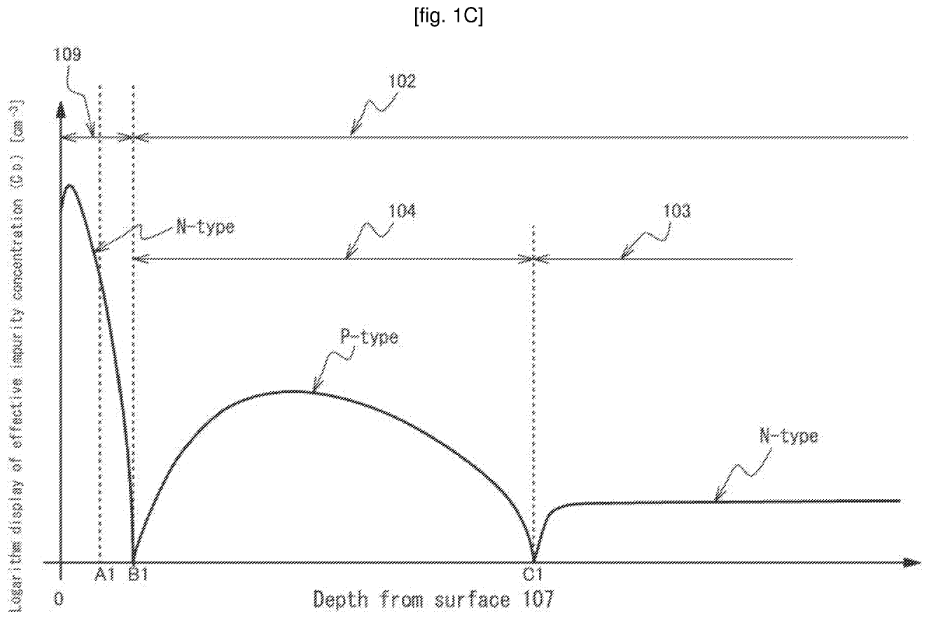

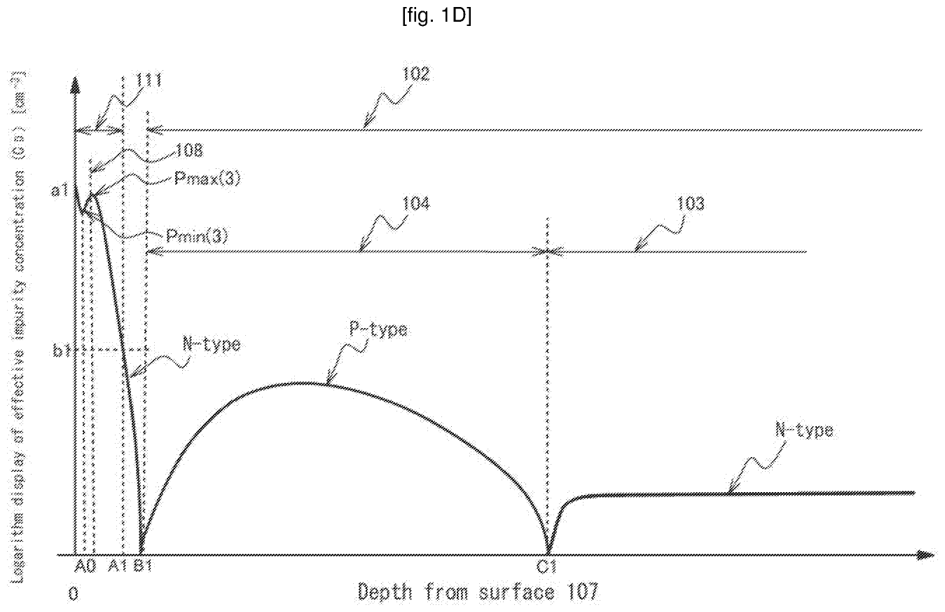

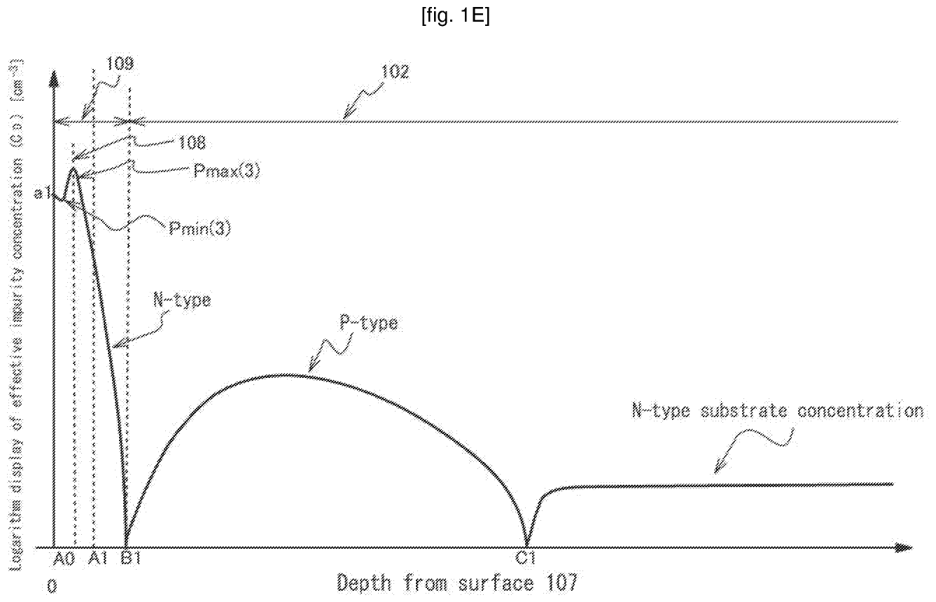

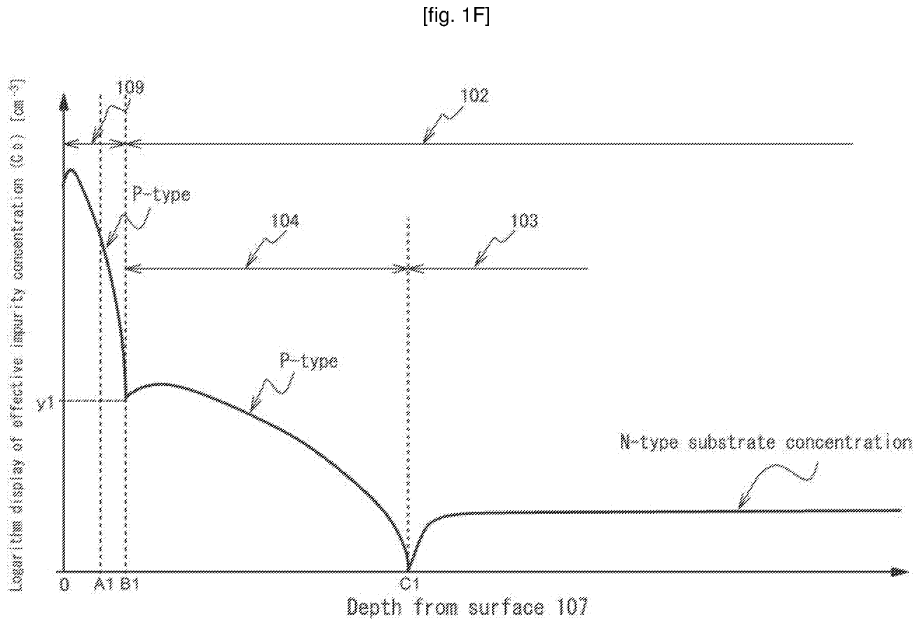

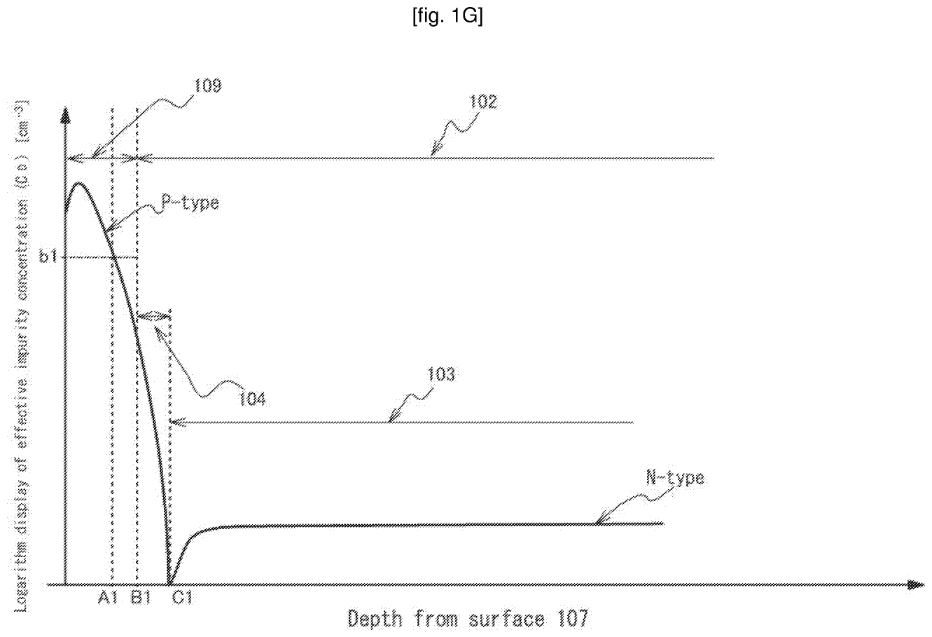

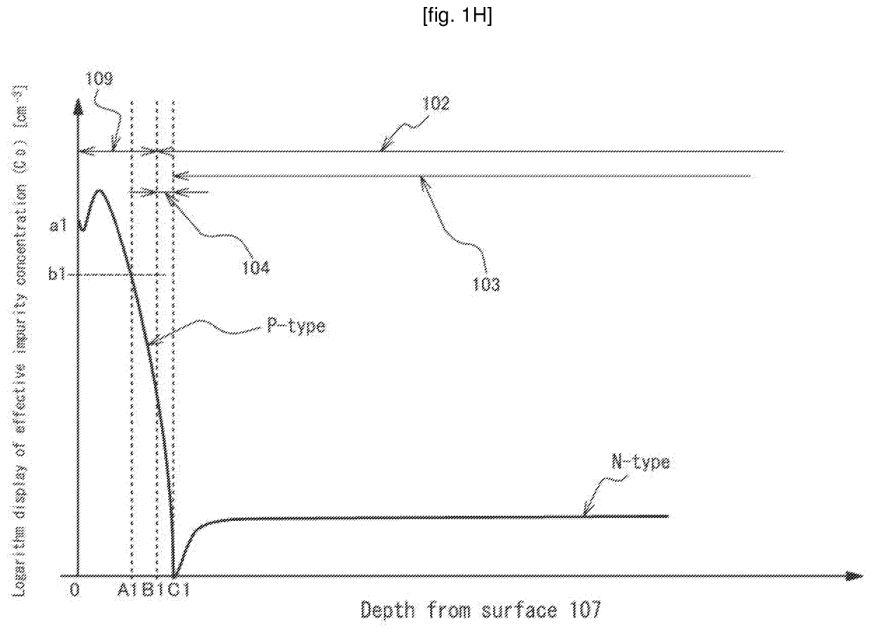

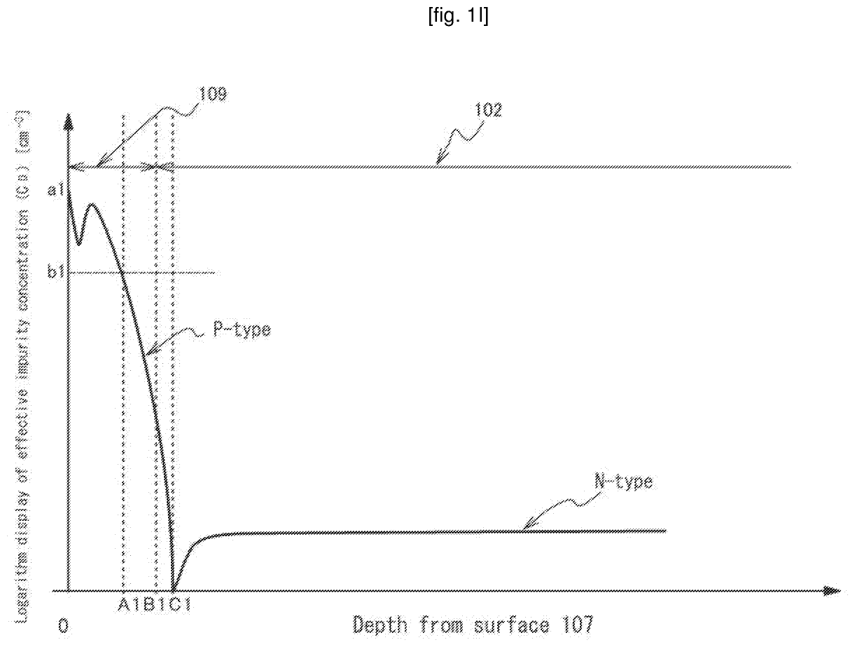

A solar battery 100 illustrated in FIG. 1A includes a substrate 101, a photovoltaic power generating part 100a, an intermediate layer 113, and a passivation layer 114.

The photovoltaic power generating part 100a includes a photovoltaic power generating layer 102 and an ultraviolet ray (UV) deterioration preventing layer 109.

The photovoltaic power generating layer 102 is configured by a layer region (1) 103 and a layer region (2) 104 configured by semiconductors.

Semiconductor impurities are contained in and a predetermined semiconductor polarity is imparted to the layer region (1) 103 and the layer region (2) 104.

For example, a preferred typical example is, when the layer region (1) 103 has n-type polarity, the layer region (2) 104 has p-type polarity.

In the present application, a layer region having n-type polarity or p-type polarity technically means that the layer region contains n-type or p-type semiconductor impurities in an amount contributing to the semiconductor polarity of the layer region (an effective semiconductor impurity content), and is imparted with the n-type or p-type semiconductor polarity.

The UV deterioration preventing layer 109 is configured by a layer region (3) 110 and a layer region (4) 111, contains semiconductor impurities, and is imparted with a predetermined semiconductor polarity. The semiconductor impurities contained in the UV deterioration preventing layer 109 are contained in a concentration distribution in a layer thickness direction of the UV deterioration preventing layer 109 (a layer depth direction from an upper surface 107 of the UV deterioration preventing layer 109). The concentration distribution in this case refers to the distribution (hereinafter referred to as “effective semiconductor impurity concentration distribution”) of the concentration (hereinafter also referred to as “effective semiconductor impurity concentration”) of semiconductor impurities contributing to the semiconductor polarity of the UV deterioration preventing layer 109. Then, hereinafter, the effective semiconductor impurity concentration at a depth (D) from the surface 107 may be referred to as an effective semiconductor impurity distribution concentration (C_{D}).

In the present invention, by setting this effective semiconductor impurity concentration distribution as described below, it is possible to effectively prevent or substantially prevent deterioration of photovoltaic power generating force due to ultraviolet exposure of the solar battery 100.

In the present invention, the layer region (4) 111 includes a region having a high effective semiconductor impurity concentration (C_{D}) in a depth direction of the layer, and a maximum value (C_{D}Max) of the effective semiconductor impurity distribution concentration (C_{D}) is provided. That is, as illustrated in FIG. 1B, the maximum value (C_{D}Max) of the effective semiconductor impurity distribution concentration (C_{D}) is provided at a maximum value position 108 in the layer region (4) 111.

A numerical range of the maximum value (C_{D}Max) and a depth (Dmax) at which the maximum value (C_{D}Max) is positioned (=“depth of position A0”) is an important technical factor in achieving maximum prevention of deterioration of photovoltaic power generating force to due to the history of ultraviolet exposure by the solar battery 100.

In the present invention, the preferred maximum value (C_{D}Max) and depth (Dmax) are preferably within the following numerical range.

1×10¹⁹/cm³≤Maximum value (C_{D}Max)≤4×10²⁰/cm³ Formula (1)

With the maximum value (C_{D}Max) set within the range of Formula (1), even when a fixed charge or interface state is generated by the irradiation of UV light in an oxide film (natural oxide film) formed on a silicon layer surface of the solar battery interior or on the interface between the oxide film and the silicon layer, carriers or impurity ions in the layer region (4) 111 can combine electric lines of force with the fixed charge, and thus do not substantially change in the internal electric field, and can make the interface state inactive so as not to serve as a recombination center. When the maximum value (C_{D}Max) deviates from the range of Formula (1), the effect described above becomes difficult to effectively obtained, which is not preferred.

0<Depth (Dmax)≤4 nm Formula (2)

The power generation efficiency for UV light can be improved by setting the range of the position A0 (=“depth (Dmax)”) of the maximum value (C_{D}Max) to the range of Formula (2).

When the position A0 (=“depth (Dmax)”) of the maximum value (C_{D}Max) exceeds 4 nm, a photocharge photoelectrically converted on the side closer to the silicon surface than the position of the maximum value does not readily reach the photovoltaic power generating layer 102. That is, because the probability that the photocharge generated by the irradiation of UV light having a short penetration length in the silicon layer is eliminated due to recombination increases, the photocharge photoelectrically converted is less likely to contribute to the generation of photovoltaic power, and thus a lowering trend in the power generation efficiency can be seen.

Preferably, a layer thickness (d1) (nm) of the layer region (4) 111 is within the following range:

(“Depth D(A0) of Position (A0)” 108 or “Depth (Dmax)”)<d1=(“Depth D(A1) of Position (A1)”)≤20 nm Formula (3)

“Where, “Depth D (A1) of Position (A1)” is defined as the depth of the position where the effective impurity distribution concentration (C_{D}) is one-half of the maximum value (C_{D}Max).”

With the layer thickness (d1) set within the range described above, the total number of effective impurities contained in the layer region (4) 111 can be made larger than the number of fixed charges and the number of interface states generated by irradiation of UV light.

When the layer thickness (d1) exceeds 20 nm, the internal electric field changes due to the fixed charges and the interface states generated by the irradiation of UV light, and the power generation efficiency lowers, which is not preferred.

Preferably, the layer thickness (d1+d2) of the UV deterioration preventing layer 109 is within the following range:

2 nm≤(d1+d2)≤60 nm Formula (4)

When the layer thickness (d1+d2) is less than 2 nm, the total number of effective impurities contained in the layer region (4) is less than the number of fixed charges and the number of interface states generated by the irradiation of UV light, lowering power generation efficiency. Further, when the layer thickness (d1+d2) exceeds 60 nm, the internal electric field resulting from a depletion layer formed by the PN junction becomes difficult to form near the silicon surface, making it difficult to transport the photocharge to the photovoltaic power generating layer. Thus, such thicknesses are not preferred.

It should be noted that, in the solar battery 100 illustrated in FIG. 1A, an electrode (for example, a light-receiving surface electrode or a back surface electrode) for taking out electric power to the outside is omitted.

When another layer is further provided on the UV deterioration preventing layer 109 and said another layer is provided directly on the UV deterioration preventing layer 109, the interface between the UV deterioration preventing layer 109 and said another layer or a surface state or a local state near the UV degradation preventing layer 109 side of the interface is formed, which causes a reduction in power generation efficiency. In order to avoid this, the intermediate layer 113 is formed by using an appropriate material under appropriate manufacturing methods and conditions.

Further, the intermediate layer 112 can also be imparted with a reflection preventing function in addition to the purpose described above, and serve as an anti-reflection film.

A surface layer 113 called a coating layer or sealing layer is, for example, provided for the purpose of imparting the solar battery 100 with water resistance, rain resistance, pollution resistance, or the like, so as to not reduce the power generation capacity and prevent a reduction in useful life.

FIG. 1B shows one of preferred examples of the effective distribution concentration of semiconductor impurities (“effective semiconductor impurity distribution concentration (C_{D})”) contained in the photovoltaic power generating part 100a. In FIG. 1B, the horizontal axis represents a depth from the surface 107, and the vertical axis represents the logarithm display of the effective semiconductor impurity distribution concentration (C_{D}).

The same applies to the horizontal axis and the vertical axis in the subsequent FIG. 1C to FIG. 1I.

The curve of the effective distribution concentration of semiconductor impurities shown in FIG. 1B has three peaks (“Pmax (1), Pmax (2), Pmax (3)”), and can be divided into three regions per peak.

The solar battery 100 indicated in FIG. 1B includes the three regions of the layer region (1) 103, the layer region (2) 104, and the UV deterioration preventing layer 109 and, in each region, the maximum value (peak) of the effective semiconductor impurity distribution concentration (C_{D}) is provided. That is, the solar battery 100 has an effective semiconductor impurity distribution concentration (C_{D}) and is provided with maximum values (peaks) at a position of a depth D1 in the layer region (1) 103, a position of a depth D2 in the layer region (1) 103, and the position of the depth 108 in the UV deterioration preventing layer 109.

The curve of the effective semiconductor impurity distribution concentration (C_{D}) shown in FIG. 1B has inflection points at positions (points) B1 (“(B1, 0) when expressed using coordinates”) and C1 (“(C1, 0) when expressed using coordinates”).

Semiconductor junctions 105 (1), 105 (2) are formed on contact surfaces of the layer region (1) 103 and the layer region (2) 104, and the layer region (2) 104 and the UV deterioration preventing layer 109, respectively.

Particularly important in the present invention are the shape of the curve of the effective distribution concentration of the semiconductor impurities in the UV deterioration preventing layer 109, and the values of the horizontal axis and the vertical axis.

In order to achieve the purpose of the present invention effectively, according to the results inductively derived from the results of a series of many experiments of making the device of the inventors, and measuring, verifying, and simulating the device characteristics, preferably the peak Pmax (3) (maximum point) in the UV deterioration preventing layer 109 is in the layer thickness of up to 4 nm in the UV deterioration preventing layer 109 with reference to the surface 107, and the value thereof (also referred to as “peak value” or “maximum value”) is at least 1×10¹⁹/cm³. The upper limit is preferably 4×10²⁰/cm³. In addition, preferably the curve of the effective distribution concentration of the semiconductor impurities on the left side (“layer region (2) 104” side) from the peak Pmax (3) is sharply oriented downward.

From the many experimental results of the inventors of the present application, it is found that, given A0 (108) as the peak position from the surface 107, it is more preferable to reduce the concentration to at least a half value (per cm³) of the maximum value (C_{D}Max) at a depth position A1 from the surface 107. That is, when explained using the example of FIG. 1B, the following is preferred at the depth position A1:

b1=Half value (per cm³) of Maximum value (C_{D}Max) Formula (5)

Experimental results show that it is technically important to set the peak Pmax (3) as close as possible to the surface 107 for the depth position A1.

Therefore, in the present invention, design is preferably carried out so as to satisfy Formula (3).

When the depth position A1 is equal to or lower than the depth position (A0) 108 (the “peak Pmax (3)” does not exist in the “layer region (4) 111”), the total number of effective impurities contained in the layer region (4) 111 is less than the number of fixed charges and the number of interface states generated by the irradiation of UV light, thereby lowering the power generation efficiency. When the depth position A1 exceeds 20 nm, the internal electric field generated by the change in the depth direction of the effective semiconductor impurity distribution concentration (C_{D}) becomes small, making it difficult to transport the photocharge generated by the UV light having a short penetration length to the photovoltaic power generating layer. In any case, deviation of the depth position (A1) from the range in Formula (3) is not preferred in the present invention.

In the example of FIG. 1B, when the layer region 103 is the n-type, for example, the layer region 104 is the p-type and the layer region 109 is the n-type. In the case of the present invention, it is easily conceivable that the layer regions may have a polarity in which n-type and the p-type are switched, which is the category of the present invention.

In the example of FIG. 1B, in the case of the layer regions 103, 104 as well, the peaks Pmax (1), Pmax (2) are provided in the concentration distribution curve at a depth position (D1) 106 (1) and a depth position (D2) 106 (2) from the surface 107, respectively.

The example of FIG. 1C is substantially the same as in FIG. 1B except that the effective concentration distribution of the semiconductor impurities in the layer region 103 is substantially flat.

The example of FIG. 1D is substantially the same as in FIG. 1C except that the effective concentration distribution of the semiconductor impurities in the layer region (4) 111 differs as illustrated.

In the cases of FIG. 1B and FIG. 1C, the effective distribution concentration curve of the semiconductor impurities of peak Pmax (3) on the left side in the graph reaches the vertical axis with a lowering tendency, but in the case of FIG. 1D, the distribution concentration decreases and reaches a minimum point Pmin (3), subsequently increases once again, and then reaches point al on the vertical axis. The distribution concentration value at point al is the same as or greater than the distribution concentration value at peak Pmax (3).

Another preferred example is shown in FIG. 1E.

FIG. 1E is substantially the same as in FIG. 1D except that the distribution concentration curve in the UV deterioration preventing layer 109 differs.

In the case of FIG. 1E, after the distribution concentration decreases and reaches the minimum point Pmin (3), it increases once again and reaches the point al on the vertical axis. The distribution concentration value at point al is the same as or greater than the distribution concentration value at peak Pmax (3).

FIG. 1F shows another preferred example.

The curve of the effective semiconductor impurity distribution concentration (C_{D}) of a solar battery 100F shown in FIG. 1F differs from the curve of the effective semiconductor impurity distribution concentration (C_{D}) in the case of FIG. 1C in terms of the following.

That is, the curve of the effective semiconductor impurity distribution concentration (C_{D}) of the solar battery shown in FIG. 1F has three inflection points as in the case of FIG. 1C, but the inflection point at position B1 is provided at the coordinate points (B1, y1), not on the horizontal axis. The semiconductor polarity of the layer region (1) 103, the layer region (2) 104, and the UV deterioration preventing layer 109 is n/p/p or p/n/n, as illustrated.

FIG. 1G shows yet another preferred example.

The curve of the effective semiconductor impurity distribution concentration (C_{D}) of a solar battery 100G shown in FIG. 1G differs from the curve of the effective semiconductor impurity distribution concentration (C_{D}) in the case of FIG. 1F in terms of the following.

That is, the curve of the effective semiconductor impurity distribution concentration (C_{D}) of the solar battery shown in FIG. 1G, unlike the case of FIG. 1F, has only one inflection point or only substantially one inflection point.

At a boundary between the layer region (2) 104 and the UV deterioration preventing layer 109, the curve of the effective semiconductor impurity distribution concentration (C_{D}) changes continuously. Then, the semiconductor polarity of the layer region (2) 104 and the UV deterioration preventing layer 109 are the same. That is, the solar battery shown in FIG. 1G has a layer structure of the semiconductor polarities of n/p/p or p/n/n from the side opposite to the incident side of the sunlight.

FIG. 1H shows yet another preferred example.

The curve of the effective semiconductor impurity distribution concentration (C_{D}) of a solar battery 100H shown in FIG. 1H is substantially the same as in FIG. 1G except that the curve has the maximum peak Pmax (3) and the minimum peak Pmin (3) in the portion of the UV deterioration preventing layer 109, as in the case of FIG. 1E.

FIG. 1I shows yet another preferred example.

The curve of the effective semiconductor impurity distribution concentration (C_{D}) of a solar battery 100I shown in FIG. 1I is substantially the same as in FIG. 1G except that the curve has the maximum peak Pmax (3) and the minimum peak Pmin (3) in the portion of the UV deterioration preventing layer 109, as in the case of FIG. 1D.

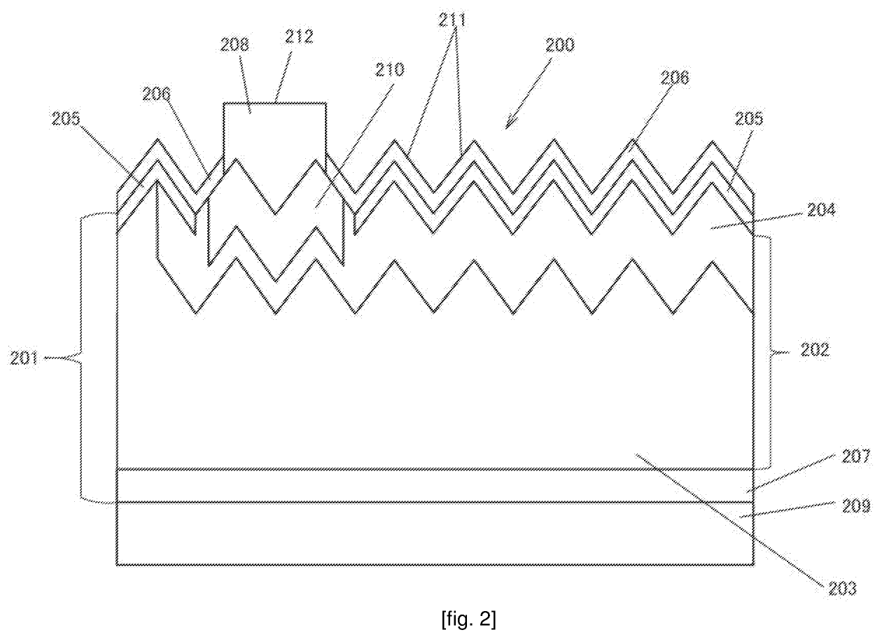

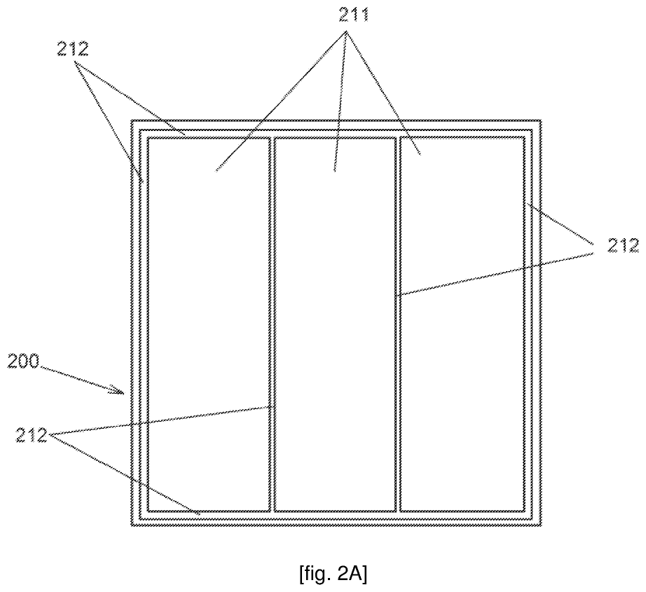

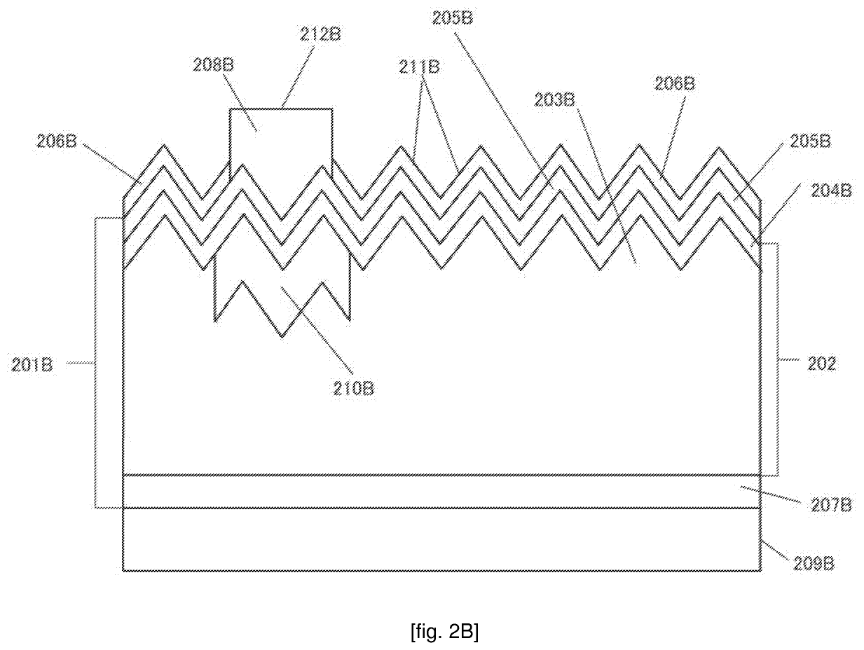

Another preferred example of an embodiment of the present invention is illustrated in FIG. 2.

FIG. 2 schematically shows a structure of a solar battery 200.

In the solar battery 100 illustrated in FIG. 2, the layer structure on the light irradiation side has a sawtooth-like, a pyramid-like, or a corrugated uneven structure. With such an uneven structure provided, irradiation light can be efficiently taken into the solar battery 200 by the multiple reflection effect.

The solar battery 200 includes a crystalline semiconductor part 201. The crystalline semiconductor part 201 is configured by a semiconductor material such as a monocrystalline, a polycrystalline, or a micro-/nano-crystalline silicon (Si) semiconductor material, but is preferably configured by a monocrystalline silicon (Si) semiconductor material.

The crystalline semiconductor part 201 includes a photovoltaic power generating layer 202, a UV deterioration preventing layer 205, and a back surface high concentration layer 207 in an interior thereof.

The photovoltaic power generating layer 202 includes a layer region (1) 203 and a layer region (2) 204. A semiconductor junction is formed on a contact surface of the layer region (1) 203 and the layer region (2) 204. This semiconductor junction is, for example, formed by setting one of the layer region (1) 203 and the layer region (2) 204 to a certain semiconductor polarity, and the other to a semiconductor polarity different from the polarity. Specifically, one of the layer region (1) 203 and the layer region (2) 204 is set to a P type and the other is set to an N type.

The crystalline semiconductor part 201 includes an anti-reflection layer 206 and a light-receiving surface electrode 208 on the light irradiation side (upper side in the drawing), and a back surface electrode 209 on the side (lower side in the drawing) opposite to the light irradiation side.

The back surface high concentration layer 207 is provided to minimize or substantially eliminate an electrical resistance between the layer region (1) 203 and the back surface electrode 209 and extract the photovoltaic power as efficiently as possible. For that purpose, the back surface high concentration layer 207 contains semiconductor impurities of the desired semiconductor polarity at a high concentration. Specifically, for example, when the crystalline semiconductor part 201 is configured by a Si semiconductor material, for example, it is configured by a P⁺-type or N⁺-type Si semiconductor material.

Provided for the same purpose is an upper surface high concentration layer 210 provided under side of the light-receiving surface electrode 208.

The back surface electrode 209 is configured by, for example, aluminum (A1) or the like.

In the solar battery 200, the UV deterioration preventing layer 205 is not provided on under side, that is a light-shielded side, of the light-receiving surface electrode 208, but may be provided on under side, that is a light-shielded side, of the light-receiving surface electrode 208 for manufacturing efficiency.

The concentration distribution of the semiconductor impurities in the UV deterioration preventing layer 205 adopts any one of the patterns of the concentration distribution curve shown in FIG. 1B to FIG. 1I.

FIG. 2A schematically shows an upper surface of the solar battery 200 (the surface viewed from above in FIG. 2).

The light-receiving surface electrode 208 is disposed around the solar battery 200 and around an incident surface 211 so that a surface 212 of the light-receiving surface electrode 208 is on the light irradiation side, as illustrated. The light-receiving surface electrode 208 is configured by, for example, silver (Ag) or the like.

FIG. 2B shows another example of a preferred embodiment of the present invention as a modified example of the solar battery 200 illustrated in FIG. 2.

A solar battery 200B illustrated in FIG. 2B has a layer structure and a curve of the effective semiconductor impurity distribution concentration (C_{D}) similar to those of the solar batteries shown in FIG. 1G to FIG. 1I.

Next, one of typical manufacturing examples of the solar battery according to the present invention will be specifically described.

The following is a preferred manufacturing example of the main part of the solar battery of the present invention having a p+pn type element structure showing the effective concentration distribution in FIG. 1F.

Cases where the polarity of the element structure is a reverse polarity, needless to say, also fall under the category of the present invention in the technical field.

The solar battery of the present invention can be formed by a conventional semiconductor manufacturing technique. Accordingly, in the following process descriptions, matters that are self-evident for a technician in the field are omitted and the main points are simply described.

Step (1): An Si wafer (semiconductor substrate) is prepared. Here, an n-type Si wafer having an impurity concentration of 1×10¹⁴ cm⁻³ is prepared.

The lower the impurity concentration of the Si wafer, the higher the sensitivity to a long light wavelength band, and thus a lower impurity concentration is preferred. However, needless to say, impurity concentrations other than 1×10¹⁴ cm⁻³ may be used. Further, a p-type Si wafer may be used.

Step (2): A 7-nm SiO₂ film is formed on the semiconductor substrate (n-type Si wafer) surface. Here, water oxidation is performed at 750° C., but chemical vapor deposition may be used.

Further, prior to this process, a surface texture structure for suppressing the reflection of incident light may be formed using a wet etching process or the like.

Step (3): Ion implantation is performed to form an embedded p-type semiconductor region.

The ion implantation conditions are such that the ion species is B⁺, the implantation energy is 20 keV, and the dose is 4×10¹² cm⁻².

Step (4): Heat treatment is performed to activate the impurity atoms implanted in Step (4).

Here, heat treatment at 1,000° C. is performed for five seconds in a nitrogen atmosphere.

Step (5): Ion implantation is performed to form a UV deterioration preventing layer.

The ion implantation conditions are such that the ion species is BF₂⁺, the implantation energy is 8 keV, and the dose is 8.0×10¹³ cm².

Step (6): Here, to form an insulating film between wiring layers, a SiO₂ film having a thickness of 300 nm is formed using a chemical vapor disposition method.

Step (7): A contact hole for connecting an embedded p-type semiconductor region and wiring is made.

Here, the insulating film between wiring layers is etched by wet etching.

Step (8): Ion implantation is performed to form a p⁺-semiconductor layer in the contact hole opening region.

Here, the ion species is BF₂⁺, the energy is 35 keV, and the dose is 3.0×10¹⁵ cm².

Step (9): Heat treatment is performed to activate the impurity atoms implanted in step (5) and step (8). Here, heat treatment at 950° C. is performed for one second in a nitrogen atmosphere.

Step (10): To form the A1 wiring, an A1 film having a thickness of 500 nm is formed using a sputtering method.

Step (11): To form the A1 wiring, etching and patterning are performed on a part of the A1 region by dry etching.

Step (12): An A1 electrode for connection with the substrate is formed on the Si wafer back surface.

The solar battery of the present invention created as described above has high sensitivity to the light wavelength band of 200 to 1,100 nm and, in particular, has an ideal quantum efficiency to the light wavelength band of 200 to 900 nm. Furthermore, it has been found that the sensitivity does not deteriorate even when intense ultraviolet light is irradiated using an ultra-high pressure mercury lamp as a light source.

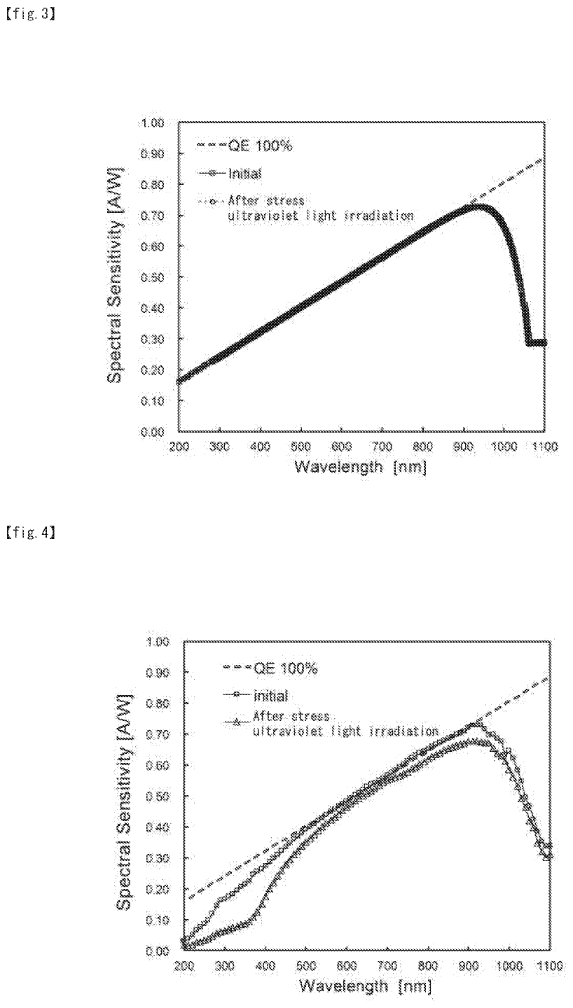

FIG. 3 is a graph showing a typical example of a light-receiving sensitivity of the solar battery according to the present invention.

### EXAMPLES AND COMPARATIVE EXAMPLES

Examples and comparative examples of the present invention are described below.

Although the examples described below are typical examples related to the present invention, they are not intended to uniquely limit the present invention, but indicate the superiority of the present invention.

Samples (1) to (4) were prepared, changing only the dose conditions in the step (5). The dose was 2.0×10¹³ cm² in sample (1) (Example 1), 8.0×10¹⁴ cm⁻² in sample (2) (Example 2), 1.0×10¹³ cm⁻² in sample (3) (Comparative Example 1), and 1.6×10¹⁵ cm⁻² in sample (4) (Comparative Example 2).

The conditions of the other steps were the same as those mentioned above. The C_{D}Max of the prepared samples was 1×10¹⁹ cm⁻³ for sample (1), 4×10²⁰ cm⁻³ for sample (2), 5×10¹⁸ cm⁻³ for sample (3), and 8×10²⁰ cm⁻³ for sample (4).

Further, A0 was 2 nm and A1 was 8 nm in all samples (1) to (4), and all samples (1) to (4) satisfied the condition of Formula (3). Sample (1) satisfied the lower limit of Formula (1), sample (2) satisfied the upper limit of Formula (2), sample (3) did not satisfy the lower limit of Formula (1), and sample (4) did not satisfy the upper limit of Formula (1).

Sample (5) (Comparative Example 3) was prepared for further comparison. In sample (5), the ion species was BF₂⁺, the implantation energy was 25 keV, and the dose was 3.0×10¹³ cm⁻² in the step (5).

In the prepared sample (5), C_{D}Max was 1×10¹⁹ cm⁻³ and A1 was 25 nm, and the condition of Formula (1) was satisfied, but the condition of Formula (3) was not satisfied.

Samples (1) and (2) obtained the same characteristics as in FIG. 3. On the other hand, in sample (3), although the initial characteristics obtained were the same as in FIG. 3, the deterioration in sensitivity of the ultraviolet light band after irradiation of the ultraviolet light was large, and the preferred characteristics were not obtained. Further, in sample (4), as a result of introducing impurities greater than or equal to a solid solubility, the dark current was high and preferred characteristics were not obtained. Furthermore, in sample (5), although the initial characteristics obtained were the same as in FIG. 3, the deterioration in sensitivity of the ultraviolet light band after irradiation of the ultraviolet light was large, and the preferred characteristics were not obtained.

Next, as a comparison, description will be given of a manufacturing example of a solar battery without the UV deterioration layer according to the present invention, and the characteristics of light-receiving sensitivity.

Step (1A): A Si wafer (semiconductor substrate) is prepared. Here, a p-type Si wafer having an impurity concentration of 1×10¹⁴ cm⁻³ is prepared.

Step (2A): An approximate 1-nm natural oxide film is formed by exposing the semiconductor substrate (p-type Si wafer) surface to the atmosphere. Further, prior to this process, a surface texture structure for suppressing the reflection of incident light is formed using a wet etching process.

Step (3A): To form a photovoltaic power generating layer, ion implantation is performed to form an n-type semiconductor region for forming a p-n junction with a p-type semiconductor substrate.

The ion implantation conditions are such that the ion species is As⁺, the implantation energy is 35 keV, and the dose is 3×10¹⁵ cm².

Step (4A): Heat treatment is performed to activate the impurity atoms implanted in step (3A).

Here, heat treatment at 1,000° C. is performed for five seconds in a nitrogen atmosphere.

Step (5A): To form the A1 wiring, an A1 film having a thickness of 500 nm is formed using a sputtering method.

Step (6A): To form the A1 wiring, etching and patterning are performed on a part of the A1 region by dry etching.

Step (7A): An A1 electrode for connection with the substrate is formed on the Si wafer back surface.

FIG. 4 is a graph showing an example of the light-receiving sensitivity of the solar battery (comparative sample 4) created in the above-described steps. The sensitivity characteristics were less than ideal in the wavelength band of light wavelength of 450 nm or less from the initial period of creation. This is particularly because there was no internal electric field that efficiently transports the photocharge generated by the light wavelength having a short penetration length to the photovoltaic power generating layer. Further, after the ultra-high pressure mercury lamp was irradiated, the sensitivity in the light wavelength band of 380 nm or less deteriorated significantly, and the sensitivity in the wavelength band of 600 nm or less also deteriorated from initial characteristics. As a result, the solar power generation efficiency deteriorated by about 8% compared to the initial value.

Although the several preferred examples of embodiments of the present invention and modified examples thereof described above using FIG. 1A to FIG. 3 are shown to be excellent solar batteries, it is clear from the above description that the present invention cannot be limited thereto.

The present invention is not limited to the above-described embodiments, and various changes and modifications can be made within the spirit and scope of the present invention. Therefore, to apprise the public of the scope of the present invention, the following claims are attached.

### DESCRIPTIONS OF REFERENCE NUMERALS

100, 200, 200B Solar battery
100a Photovoltaic power generating part
102, 202, 202B Photovoltaic power generating layer
103, 203, 203B Layer region (1)
104, 204, 204B Layer region (2)
105 (1), 105 (2) Semiconductor junction
106 (1), 106 (2) Peak position of concentration distribution curve
107 Surface
108 Maximum value position
109, 205, 205B UV deterioration preventing layer
110 Layer region (3)
111 Layer region (4)
112 Intermediate layer
113 Surface layer
201, 201B Crystalline semiconductor part
206, 206B Anti-reflection film
207, 207B Back surface high concentration layer
208, 208B Light-receiving surface electrode
209, 209B Back surface electrode
210, 210B Upper surface high concentration layer
211, 211B Incident surface

1. A solar battery comprising:
an n-type or p-type silicon (Si) semiconductor substrate;
a semiconductor layer having a polarity (II) opposite to a polarity (I) of the semiconductor substrate and forming a semiconductor junction with the semiconductor substrate; and
a UV deterioration preventing layer provided directly on the semiconductor layer, having a polarity (III) opposite to the polarity (II), having a layer thickness (d1+d2) within a range of 2 to 60 nm, and containing semiconductor impurities of the polarity (III) including semiconductor impurities contributing to the polarity (III) distributed in concentration in a layer thickness direction and having a maximum value (C_{D}Max) of the concentration distribution in an interior thereof, wherein
the maximum value (C_{D}Max) is within the following range:
1×10¹⁹/cm³≤Maximum value (C_{D}Max)≤4×10²⁰/cm³ Formula (1)
and has a half value (b1) at a depth position (A1) from a surface of the UV deterioration preventing layer on a light incident side, and
the depth position (A1) is within the following range:
Depth position (A0) of Maximum value (C_{D}Max)<(“Depth position (A1)”)≤20 nm Formula (3)

2. A solar battery comprising:
a photovoltaic power generating layer including a semiconductor junction; and
a UV degradation preventing layer provided directly on the photovoltaic power generating layer, wherein
the UV deterioration preventing layer has a layer thickness (d1+d2) within a range of 2 to 60 nm, and contains semiconductor impurities including semiconductor impurities contributing to the semiconductor polarity of the UV deterioration preventing layer distributed in concentration in a layer thickness direction and having a maximum value (C_{D}Max) of the concentration distribution in an interior thereof,
the maximum value (C_{D}Max) is within the following range:
1×10¹⁹/cm³≤Maximum value (C_{D}Max)≤4×10²⁰/cm³ Formula (1)
and has a half value (b1) at a depth position (A1) from a surface of the UV deterioration preventing layer on a light incident side, and
the depth position (A1) is within the following range:
Depth position (A0) of Maximum value (C_{D}Max)<(“Depth position (A1)”)≤20 nm Formula (3)

3. A photoelectric converter comprising:
an n-type or p-type silicon (Si) semiconductor substrate;
a semiconductor layer having a polarity (II) opposite to a polarity (I) of the semiconductor substrate and forming a semiconductor junction with the semiconductor substrate; and
a UV deterioration preventing layer provided directly on the semiconductor layer, having a polarity (III) opposite to the polarity (II), having a layer thickness (d1+d2) within a range of 2 to 60 nm, and containing semiconductor impurities of the polarity (III) including semiconductor impurities contributing to the polarity (III) distributed in concentration in a layer thickness direction and having a maximum value (C_{M}Max) of the concentration distribution in an interior thereof, wherein
the maximum value (C_{D}Max) is within the following range:
1×10¹⁹/cm³≤Maximum value (C_{D}Max)≤4×10²⁰/cm³ Formula (1)
and has a half value (b1) at a depth position (A1) from a surface of the UV deterioration preventing layer on a light incident side, and
the depth position (A1) is within the following range:
Depth position (A0) of Maximum value (C_{D}Max)<(“Depth position (A1)”)≤20 nm Formula (3)

4. A photoelectric converter comprising:
a photoelectron generating layer including a semiconductor junction; and
a UV degradation preventing layer provided directly on the photoelectron generating layer, wherein
the UV deterioration preventing layer has a layer thickness (d1+d2) within a range of 2 to 60 nm, and contains semiconductor impurities including semiconductor impurities contributing to the semiconductor polarity of the UV deterioration preventing layer distributed in concentration in a layer thickness direction and having a maximum value (C_{D}Max) of the concentration distribution in an interior thereof,
the maximum value (D_{D}Max) is within the following range:
1×10¹⁹/cm³≤Maximum value (C_{D}Max)≤4×10²⁰/cm³ Formula (1)
and has a half value (b1) at a depth position (A1) from a surface of the UV deterioration preventing layer on a light incident side, and
the depth position (A1) is within the following range:
Depth position (A0) of Maximum value (C_{D}Max)<(“Depth position (A1)”)≤20 nm Formula (3).
